(19) United States
(12) Patent Application Publication
(10) Pub. No.: US 2009/0039422 A1
(43) Pub. Date: Feb. 12, 2009

(54) RECESS GATE OF SEMICONDUCTOR DEVICE AND METHOD FOR FORMING THE SAME

(76) Inventor: Dae-Young Kim, Suwon-si (KR)

Correspondence Address: SHERR & VAUGHN, PLLC, 620 HERNDON PARKWAY, SUITE 200, HERNDON, VA, 20170, US

(21) Appl. No.: 12/188,164

(22) Filed: Aug. 7, 2008

(30) Foreign Application Priority Data
Aug. 9, 2007 (KR) 10-2007-080099

(51) Int. Cl. H01L 21/28; H01L 29/78; H01L 21/67

(52) U.S. Cl. 257/330; 438/589; 29/25.01; 257/E21.158; 257/E29.255

(57) ABSTRACT

A method for fabricating a semiconductor device, and more particularly, a method for forming a recess gate is disclosed. The method for forming a recess gate includes forming a first nitride layer over a semiconductor substrate, forming a first nitride layer pattern by selectively etching the first nitride layer to expose a portion of the substrate, forming a spacer over a sidewall of the first nitride layer pattern, forming a recess for a gate channel region by etching the substrate using the first nitride layer pattern and the spacer as an etching mask, forming a gate oxide layer over a sidewall and a bottom surface of the recess, forming a gate poly-silicon layer pattern to bury the recess and a space defined by the spacer, and removing the first nitride layer pattern.

The present application claims priority under 35 U.S.C. 119 to Korean Patent Application No. 10-2007-080099 (filed on Aug. 9, 2007), which is hereby incorporated by reference in its entirety.

### BACKGROUND

Due to the trend towards higher integration of semiconductor devices, transistors have been reduced in size. Consequently, the distance between the source and drain, i.e. the channel length, has been reduced. A reduced channel length causes the source/drain depletion region to expand into the channel, resulting in a reduction in an effective channel length and threshold voltage. Unfortunately, a short channel effect degrades the function of the gate, which is to control the transistor. The reduced channel length, furthermore, causes a hot carrier phenomenon due to high electric fields across a semiconductor device. Impact ionization caused by the hot carrier phenomenon has a negative effect on an oxide layer, resulting in the deterioration of the oxide layer.

For these reasons, in the related art, to prevent a threshold voltage from being reduced due to the short channel effect, attempts have been made to increase the channel doping concentration to achieve a desired threshold voltage. However, increasing the channel doping concentration causes electric field convergence on source junctions and increases leakage current, deteriorating the refresh characteristics of transistors.

### SUMMARY

Embodiments relate to a method for fabricating a semiconductor device, and more particularly, to a method for forming a recess gate using a spacer. Embodiments relate to a method for forming a recess gate, which can increase an effective channel length without reducing the degree of integration of a semiconductor device.

Embodiments relate to a method for forming a recess gate of a semiconductor device which includes: forming a first nitride layer over a semiconductor substrate, forming a first nitride layer pattern by selectively etching the first nitride layer to expose a portion of the substrate, forming a spacer over a sidewall of the first nitride layer pattern, forming a recess for a gate channel region by etching the substrate using the first nitride layer pattern and the spacer as an etching mask, forming a gate oxide layer over a sidewall and a bottom surface of the recess, forming a gate poly-silicon layer pattern to bury the recess and a space defined by the spacer, and removing the first nitride layer pattern.

The first nitride layer may be formed of a thermal nitride layer to a thickness of 100 Å to 200 Å. Forming the spacer may include: successively forming an oxide layer and a second nitride layer over the first nitride layer pattern and the substrate exposed by etching; and removing the second nitride layer and the oxide layer over the first nitride layer pattern by etching the second nitride layer and the oxide layer. The etching of the second nitride layer and the oxide layer may be performed via Reactive Ion Etching (RIE) using plasma.

The oxide layer may be a TetraEthly OrthoSilicate (TEOS) layer. The etching to form the recess may be performed on the substrate via Reactive Ion Etching (RIE) using plasma. The gate oxide layer may be formed in the recess by performing a thermal oxidation process. Forming the gate poly-silicon layer pattern may include forming a gate poly-silicon layer to bury the recess and the space defined by the spacer, and flattening or planarizing the gate poly-silicon layer until the first nitride layer pattern is exposed to the outside.

Removing the first nitride layer pattern may include: forming a photoresist pattern over the gate poly-silicon layer pattern, to expose the first nitride layer pattern to the outside, etching the first nitride layer pattern using the photoresist pattern as an etching mask, and removing the photoresist pattern.

Embodiments relate to a recess gate of a semiconductor device which may include a recess formed in a semiconductor substrate, the recess defining a gate channel region of the semiconductor device. A gate oxide layer may be formed over a sidewall and a bottom surface of the recess. A spacer may be formed over the semiconductor substrate at a position adjacent the recess. A gate poly-silicon layer may fill the recess and a space defined by the spacer, the poly-silicon layer having a width which increases with height above the substrate due to a shape of the spacer. The gate oxide layer may be a thermal oxide layer. The spacer may have an oxide layer and nitride layer. The oxide layer of the spacer may be a TetraEthly OrthoSilicate (TEOS) layer.

### DRAWINGS

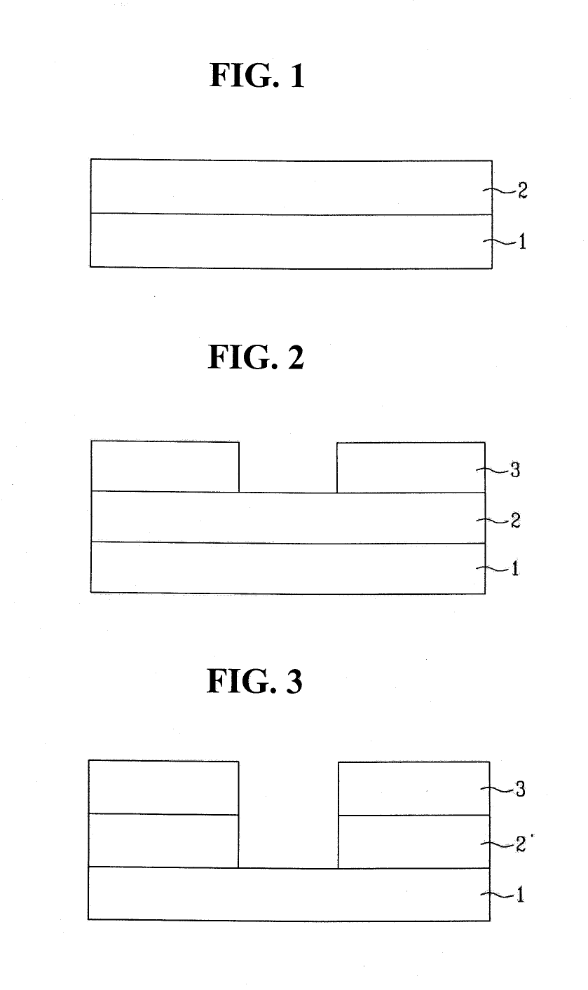

Example FIGS. 1 to 9 are process sectional views illustrating a method for forming a recess gate according to embodiments.

### DESCRIPTION

Example FIGS. 1 to 9 are process sectional views illustrating a method for forming a recess gate according to embodiments. As shown in example FIG. 1, a first nitride layer 2 may be formed over a semiconductor substrate 1. Specifically, the first nitride layer 2 may be formed by depositing a thermal nitride layer over the semiconductor substrate 1 to a thickness of approximately 100 Å to 200 Å. Here, the deposition of the thermal nitride layer may be performed via Chemical Vapor Deposition (hereinafter, referred to as “CVD”).

As shown in example FIG. 2, a photoresist pattern 3 is formed over the first nitride layer 2. The photoresist pattern 3 may be provided to form a gate. Specifically, after applying a photoresist over the first nitride layer 2, the photoresist may be subjected to a photolithography process using a reticle as a gate forming mask, to form the photoresist pattern 3.

As shown in example FIG. 3, the photoresist pattern 3 may be used as an etching mask to form a first nitride layer pattern 2′. Specifically, to form the first nitride layer pattern 2′, the first nitride layer 2 may be subjected to etching using the photoresist pattern 3 as an etching mask. Here, the etching of the first nitride layer 2 may be performed via Reactive Ion Etching (hereinafter, referred to as “RIE”) using plasma. The resulting first nitride layer pattern 2′ may be subsequently subjected to ashing and cleaning, to remove a residue of the photoresist pattern 3 present on the first nitride layer pattern 2′.

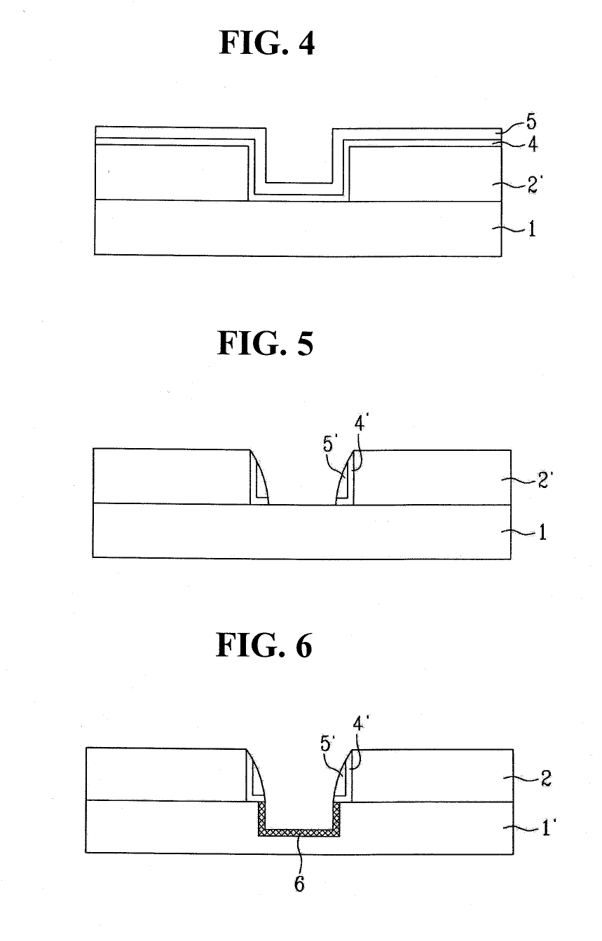

As shown in example FIG. 4, an oxide layer 4 and a second nitride layer 5 may be successively formed over an entire surface of the substrate 1 over which the first nitride layer pattern 2′ is formed. Thereafter, as shown in example FIG. 5, the oxide layer 4 and the second nitride layer 5 may be etched, to form Oxide/Nitride (ON) spacers 4′ and 5′ over opposite sidewalls of the first nitride layer pattern 2′. In this case, the spacers 4′ and 5′ may be formed via plasma RIE and the oxide layer 4 of the spacer 4′ may be prepared using a tetraethly orthosilicate (TEOS) layer.

As shown in example FIG. 6, a recess for a gate channel region may be formed. To form the recess, the substrate 1 may be subjected to plasma RIE using the first nitride layer pattern 2′ and the ON spacers 4′ and 5′ as an etching mask. Subsequently, a gate oxide layer 6 may be formed at side and bottom surfaces of the recess. The gate oxide layer 6 may be formed by performing a thermal oxidation process on the substrate exposed via the recess. For example, in embodiments, the thermal oxidation process may be performed at a temperature of 850° C. to 1,100° C. for approximately 30 minutes to 40 minutes using oxygen gas at approximately 1.5 SLM to 25 SLM.

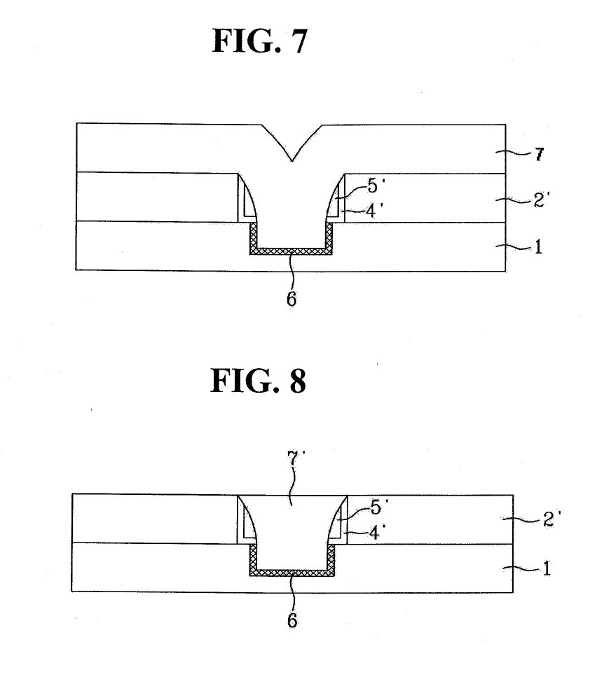

As shown in example FIG. 7, a gate poly-silicon layer 7 may be deposited over the entire surface of the substrate 1. In this case, the gate poly-silicon layer 7 may be deposited to completely bury the recess formed in the semiconductor substrate 1 and a space defined by the spacers 4′ and 5′.

As shown in example FIG. 8, the gate poly-silicon layer 7 may be subjected to a planarizing process until the first nitride layer pattern 2′ is exposed to the outside, to form a gate poly-silicon layer pattern 7′. Here, the planarizing process may be a Chemical Mechanical Polishing (CMP) process or etch back process.

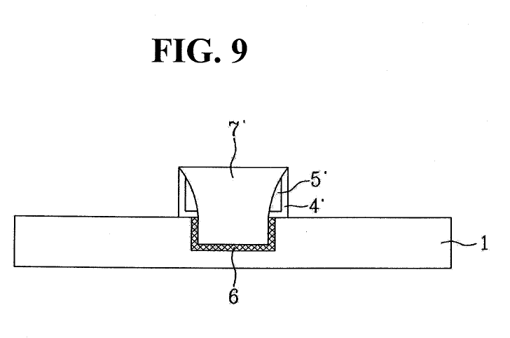

Finally, as shown in example FIG. 9, the first nitride layer pattern 2′ may be removed. Specifically, to remove the first nitride layer pattern 2′, a photoresist pattern may be formed over the gate poly-silicon layer pattern 7′. The first nitride layer pattern 2′ may be etched using the photoresist pattern as an etching mask. After completing the etching of the first nitride layer pattern 2′, the photoresist pattern may be removed.

As described above, according to embodiments, the overall gate poly-silicon layer pattern 7′ may be reduced in size while maintaining the same effective channel area as compared to the related art. This configuration can improve channel mobility and minimize short channel effects. Furthermore, as a result of providing the spacers 4′ and 5′ over opposite sides of the gate poly-silicon layer pattern 7′, the method for forming a recess gate according to embodiments may not require an additional spacer forming process.

As apparent from the above description, embodiments provide a method for forming a recess gate according to embodiments, which can increase an effective channel length without reducing the degree of integration of a semiconductor device. Further, such an increased effective channel length minimizes short channel effects and increases channel mobility. Furthermore, according to embodiments, the use of spacers can prevent etching damage, and this advantageously enables formation of a high quality gate.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first nitride layer over a semiconductor substrate;
forming a first nitride layer pattern by selectively etching the first nitride layer to expose a portion of the substrate;
forming a spacer over a sidewall of the first nitride layer pattern;
forming a recess for a gate channel region by etching the substrate using the first nitride layer pattern and the spacer as an etching mask;
forming a gate oxide layer over a sidewall and a bottom surface of the recess;
forming a gate poly-silicon layer pattern to bury the recess and a space defined by the spacer; and
removing the first nitride layer pattern.

2. The method of claim 1, wherein the first nitride layer is formed of a thermal nitride layer to a thickness of approximately 100 Å to 200 Å.

3. The method of claim 1, wherein forming the spacer comprises:
successively forming an oxide layer and a second nitride layer over the first nitride layer pattern and the substrate exposed by etching; and
removing the second nitride layer and the oxide layer over the first nitride layer pattern by etching the second nitride layer and the oxide layer.

4. The method of claim 3, wherein the etching of the second nitride layer and the oxide layer is performed via reactive ion etching using plasma.

5. The method of claim 3, wherein the oxide layer is a tetraethly orthosilicate layer.

6. The method of claim 1, wherein the etching to form the recess is performed on the substrate via reactive ion etching using plasma.

7. The method of claim 1, wherein the gate oxide layer is formed in the recess by performing a thermal oxidation process.

8. The method of claim 7, wherein the thermal oxidation process is performed at a temperature of 850° C. to 1,100° C.

9. The method of claim 8, wherein the thermal oxidation process is performed using oxygen gas at 1.5 SLM to 25 SLM.

10. The method of claim 9, wherein the thermal oxidation process is performed for approximately thirty to forty minutes.

11. The method of claim 1, wherein forming the gate poly-silicon layer pattern comprises:
forming a gate poly-silicon layer to bury the recess and the space defined by the spacer; and
planarizing the gate poly-silicon layer until the first nitride layer pattern is exposed.

12. The method of claim 11, wherein the planarizing process is a chemical mechanical polishing process.

13. The method of claim 11, wherein the planarizing process is an etch back process.

14. The method of claim 1, wherein removing the first nitride layer pattern comprises:
forming a photoresist pattern over the gate poly-silicon layer pattern, to expose the first nitride layer pattern to the outside;
etching the first nitride layer pattern using the photoresist pattern as an etching mask; and
removing the photoresist pattern.

15. An apparatus comprising:
a recess formed in a semiconductor substrate, the recess defining a gate channel region of the semiconductor device;
a gate oxide layer formed over a sidewall and a bottom surface of the recess;
a spacer formed over the semiconductor substrate at a position adjacent the recess; and
a gate poly-silicon layer filling the recess and a space defined by the spacer, the poly-silicon layer having a width which increases with height above the substrate due to a shape of the spacer.

16. The apparatus of claim 15, wherein the gate oxide layer is a thermal oxide layer.

17. The apparatus of claim 15, wherein the spacer has an oxide layer and a nitride layer.

18. The apparatus of claim 17, wherein the oxide layer of the spacer is a tetraethly orthosilicate layer.

19. An apparatus configured to:
form a first nitride layer over a semiconductor substrate;
form a first nitride layer pattern by selectively etching the first nitride layer to expose a portion of the substrate;
form a spacer over a sidewall of the first nitride layer pattern;
form a recess for a gate channel region by etching the substrate using the first nitride layer pattern and the spacer as an etching mask;
form a gate oxide layer over a sidewall and a bottom surface of the recess;
form a gate poly-silicon layer pattern to bury the recess and a space defined by the spacer; and
remove the first nitride layer pattern.

20. The apparatus of claim 19 configured to form the spacer by:
successively forming an oxide layer and a second nitride layer over the first nitride layer pattern and the substrate exposed by etching; and
removing the second nitride layer and the oxide layer over the first nitride layer pattern by etching the second nitride layer and the oxide layer.
